(19) United States
(12) Patent Application Publication
(10) Pub. No.: US 2024/0120759 A1
(43) Pub. Date: Apr. 11, 2024

(54) SYSTEMS, METHODS, AND DEVICES FOR BALANCING SERIES CONNECTED CELLS IN ENERGY STORAGE SYSTEMS

(71) Applicant: Nuvation Research Corporation, Sunnyvale, CA (US)

(72) Inventors: Manoj Mathew, Kitchener (CA); Steve Miller, Waterloo (CA); Stefan Janhunen, Waterloo (CA); Nate Wennyk, Waterloo (CA)

(21) Appl. No.: 17/937,209

(22) Filed: Sep. 30, 2022

(51) Int. Cl. H02J 7/00; H01M 10/42; H01M 10/48

(52) U.S. Cl. CPC H02J 7/00712; H01M 10/4257; H01M 10/482; H02J 7/0048; H01M 2010/4271; H01M 2010/4278

(57) ABSTRACT

Systems, methods, and devices are provided for executing cell balancing in an energy storage system. The systems, methods, and devices may comprise an imbalance estimation system and a balancing execution system. The imbalance estimation system may be configured to receive, and to determine an estimated cell imbalance and imbalance estimation uncertainty of the energy storage. The estimated cell imbalance of the energy storage may be based on a voltage input, V, representing a measured voltage associated with the energy storage device, and a probabilistic battery model associated with the energy storage device. The balancing estimation system may comprise a balancing circuit, the balancing execution system configured to partially discharge a cell via the balancing circuit based on the estimated cell imbalance of the energy storage device.

### FIELD OF INVENTION

The present disclosure relates generally to energy storage system cell balancing and, in particular, to systems for balancing cells based on estimated cell state-of-charge (“SOC”) in energy storage systems (“EES”).

### BACKGROUND

Cell balancing refers to the process of maintaining an equivalent amount of charge in series-connected cells (a stack of cells). A stack is considered balanced if the series-connected cells are at the same or similar state of charge (SOC) when the stack is fully charged. An important function of a battery management system (BMS) is to ensure the series-connected cells are balanced, and that no cells are overcharged or over discharged during the balancing process.

The two commonly used approaches for balancing cells are passive balancing and active balancing. Active balancing involves transferring energy from a cell with excess charge to one with less charge, as opposed to dissipating it as heat. While active balancing is highly efficient, it is also more expensive than passive balancing because electronics must be connected to every cell.

The second type of balancing approach is passive balancing, which involves maintaining equal charge across all cells by dissipating energy from cells with a higher charge. One typical method of passive cell balancing in series-connected cells uses only raw voltage measurements. In this voltage based cell balancing method, the voltage across each cell is measured and it is assumed that the measured voltage for each cell corresponds to the actual SOC for each cell. Then, the voltage based cell balancing method removes charge from cells that have a higher voltage than the rest of the cells in the stack. However, the assumption that the measured voltage corresponds to the actual SOC, may not be valid. For example, this assumption might not be valid if there is high cell-to-cell variability in the cell's resistance. Cells with higher resistances can generate higher voltages even if they have the same SOC as the rest of the stack. The voltage based cell balancing method has a further drawback, which is that balancing is typically restricted to specific SOC regions. For example, voltage based cell balancing may be limited to being effective only between 95% SOC and 100% SOC. This means the battery must remain within this region for an extended period of time to conduct balancing, leading to a large maintenance downtime.

Another typical method of cell balancing in a stack of cells is based on an estimate of the cell's SOC. In this estimated SOC cell balancing method, the SOC of each cell is estimated and charge is removed from cells with an estimated SOC higher than those of the other cells in the stack. However, the SOC estimate for a particular cell can be inaccurate due to modeling errors or large measurement noise. This is especially true for lithium iron phosphate cells, where the open-circuit voltage curve is flat for a large portion of the SOC range. Thus, the cell balancing method that uses only SOC estimates without accounting for SOC uncertainty could inadvertently remove charge from cells that do not need to have charge removed, thus reducing the balancing accuracy.

Systems, methods, and devices that improve the balancing of cells in a stack may be desirable. For example, it may be desirable to improve the efficiency, accuracy, and speed of balancing cells in a stack of cells for an energy storage system.

### SUMMARY

In an example embodiment, a cell balancing device in an energy storage system, may comprise: one or more cells of an energy storage device; an imbalance estimation system configured to receive, and to determine an estimated cell imbalance of the one or more cells based on: a voltage input, V, representing a measured voltage associated with the energy storage device, and a probabilistic battery model associated with the energy storage device; and a balancing execution system comprising a balancing circuit, the balancing execution system configured to partially discharge the one or more of the cells via the balancing circuit based on the estimated cell imbalance of one or more of the cells.

In an example embodiment, a battery balancing system for executing cell balancing, may comprise: a battery stack comprising one or more cells; an imbalance estimation system configured to determine an estimate of the cell imbalance of the battery stack based on: a voltage associated with the cells of battery stack; a current associated with battery stack; a probabilistic battery model associated with the cells of the battery stack; and a balancing execution system configured to receive a cell imbalance for one or more of the cells, and to discharge a balancing current from one or more of the cells using a balancing circuit.

In an example embodiment, a method for executing cell balancing, may comprise: receiving, by an imbalance estimation system, a voltage and a current associated with the one or more cells of the energy storage device; determining, by the imbalance estimation system, a SOC estimate and a SOC estimation uncertainty of the energy storage device based on the voltage and the current of the energy storage device; calculating, by the imbalance estimation system, an imbalance estimate of one or more cells of the energy storage device and an imbalance uncertainty; receiving, by a balancing execution system, an imbalance estimate and imbalance estimation uncertainty associated with the energy storage device. In various embodiments, the method for cell balancing may further comprise discharging, by the balancing execution system, a balancing current from a cell of the energy storage device; wherein the balancing execution system comprises a balancing circuit and a balancing circuit model representing the balancing circuit.

### BRIEF DESCRIPTION OF THE DRAWING FIGURES

Additional aspects of the present disclosure will become evident upon reviewing the non-limiting embodiments described in the specification and the claims taken in conjunction with the accompanying figures, wherein like numerals designate like elements, and:

FIG. 1 is a diagram illustrating an example energy storage stack of cells, in accordance with various embodiments;

FIG. 2 is a block diagram illustrating an example cell balancing system for use with a stack of cells;

FIG. 3 is a block diagram illustrating an example circuit model;

FIG. 4 is an example SOC probability distribution for estimating the cell imbalance;

FIG. 5 is an example hardware balancing module; and

FIG. 6 is a flow diagram illustrating an example method.

### DETAILED DESCRIPTION

Reference will now be made to the exemplary embodiments illustrated in the drawings, and specific language will be used herein to describe the same. It will nevertheless be understood that no limitation of the scope of the disclosure is thereby intended. Alterations and further modifications of the inventive features illustrated herein, and additional applications of the principles of the disclosure as illustrated herein, which would occur to one skilled in the relevant art and having possession of this disclosure, are to be considered within the scope of the disclosure.

In accordance with an example embodiment, systems, devices and methods are provided for balancing cells in a stack of cells of an energy storage system. In an example embodiment, the system, devices and method balance the cells taking into account the uncertainty in the SOC estimates. In the example embodiment, the cell balancing can occur over a broad range of SOC, and is not limited to a narrow range such as between 95% and 100%.

In accordance with various example embodiments, an energy storage system (“ESS”) is a system that stores and releases electrical charge. The ESS may comprise electrochemical cells, such as lead-acid batteries, nickel-cadmium batteries, nickel-metal hydride batteries, lithium-ion batteries, lithium-ion polymer batteries, zinc-air batteries, and/or the like. Moreover, the ESS may comprise any suitable rechargeable energy storage system for which cell balancing is relevant.

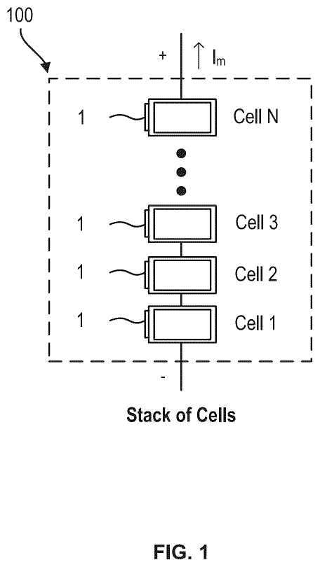

In the various example embodiments described herein, and with reference to FIG. 1, an ESS may comprise, in an example embodiment, a battery cell 1, or simply “cell” for short. In an example embodiment, the cell 1 comprises a single anode and cathode separated by electrolyte and is used to store and release electrical charge. Multiple anodes and cathodes may be joined together in parallel or series arrangements to produce cells that operate at higher voltage or current levels. The cell may be the smallest measurable unit of energy storage within an ESS. The current flowing through the cell 1 is denoted I_{M}, where a positive current flows out of the positive terminal. A typical cell can be physically arranged as a cylindrical cell, such as the 18650 and 21700 cylindrical lithium-ion format cells, button cells, prismatic cells, pouch cells, and/or the like. Moreover, a cell may comprise any chemistry and format suitable for rechargeable energy storage where cell balancing is relevant. Generally, the cell 1 may be any rechargeable energy storage device with connection points for a single voltage measurement.

Moreover, an ESS may comprise, in an example embodiment a battery module, or simply “module” for short. A module may comprise two or more cells connected in series or parallel arrangements or both series and parallel arrangements and grouped together. A module may be the smallest measurable unit in the ESS, if the individual cells are integrated into the module in such a way that measurement of voltage from the individual cells is not convenient.

Moreover, an ESS may comprise, in an example embodiment, a battery stack 100, stack of cells, or simply “stack” for short. The battery stack 100, in an example embodiment, comprises multiple cells or modules electrically connected in series. Thus, in an example embodiment, the battery stack 100 may comprise N cells, and each cell, in the stack of cells, may be noted as cell n wherein n=1 to N. It will be understood that N may be any positive integer number. For N>1, the battery stack is a number of cells, N. The systems, methods, and devices described herein may provide improved cell balancing for the N cells 1 in the battery stack 100.

A group of series connected cells may be called a stack, or stack of cells. A stack can be defined as balanced if all the series-connected cells are at the same, within some margin of error, state-of-charge when the stack is fully charged. State-of-charge (“SOC”) for a cell may be defined as a level of charge of the cell relative to the cell's capacity. State-of-charge may be expressed as a percentage of the cell's capacity, e.g., 0% may be completely discharged and 100% may be fully charged.

It is noted that a group of stacks, connected in parallel, may comprise a battery bank (not shown). Thus, an ESS may comprise, in an example embodiment, a battery bank or simply “bank” for short. Moreover, a bank may comprise any suitable number of stacks.

In an example embodiment, a cell balancing system 200, devices and methods are provided for balancing a group of cells connected in series. In various embodiments, a cell balancing system 200 may calculate imbalance estimates. For example, the imbalance estimates may be represented as deviations in state-of-charge or energy to balance the stack. In an example embodiment, the balancing may be based on SOC or energy rather than voltage, as it accounts for variation in the cell resistance among cells. In various embodiments, SOC uncertainty may be used to allow the algorithm to consider errors in the measurements and the battery model. In an example embodiment, the system is configured to take into account errors in the measurement and battery model to facilitate intelligently updating imbalance only when it is statistically significant. In an example embodiment, the cell balancing system 200 may be configured to estimate imbalance separate from executing balancing. The separation of these two processes allows the battery to balance during the battery's operation. In an example embodiment, the hardware balancing module 280 may employ a passive balancing solution. In an example embodiment, the cell balancing system 200 is configured to measure a current and a voltage related to various cells of the energy storage device, to maintain a balanced stack in order to maximize the usable energy.

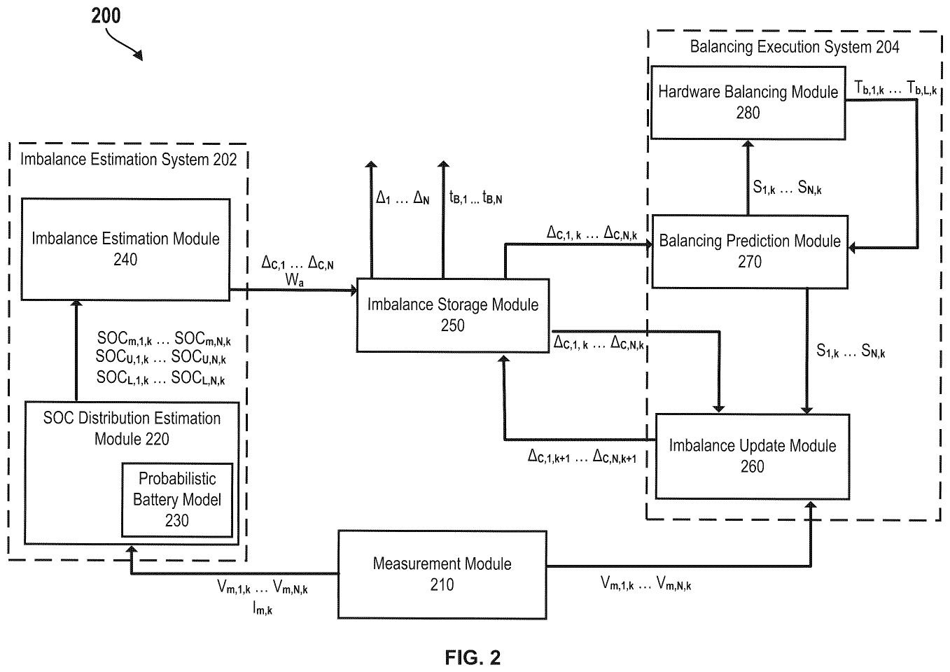

With reference now to FIG. 2, a block diagram illustrating an example cell balancing system 200 illustrates generically how the cell balancing in an ESS can be applied between cells in a stack. The cell balancing system 200 may further comprise a current measurement module and a voltage measurement module, illustrated together as measurement module 210. In various embodiments, the system 200 may further comprise a SOC distribution estimation module 220, an imbalance estimation module 240, and an imbalance storage module 250. The cell balancing system 200 may further comprise an imbalance update module 260, a balancing prediction module 270, and a hardware balancing module 280.

In various embodiments, the cell balancing system 200 may comprise an imbalance estimation system 202 and a balancing execution system 204. In various embodiments, the imbalance estimation system 202 may include the SOC distribution estimation module 220 and the imbalance estimation module 240. The imbalance estimation system 202 may receive the voltage, V, and the current, I, associated with an energy storage device or cell. The imbalance estimation system 202 may determine imbalance estimates and imbalance estimation uncertainty associated with the energy storage device. In various embodiments, the balancing execution system 204 may include the balancing prediction module 270 and the hardware balancing module 280. In various embodiments, the balancing execution system 204 may further include the imbalance update module 260. The balancing execution system 204 may receive the voltage, V, the imbalance estimates, and imbalance estimation uncertainty associated with an energy storage device or cell. The balancing execution system 204 may discharge a small balancing current from a cell based on the voltage, V, and the balancing circuit model (or stated another way, based on the voltage, imbalance estimates and imbalance estimation uncertainty provided by the imbalance estimation system 202). The balancing circuit may include a balancing resistor, a software balancing switch and cell tap connection. In various embodiments, the balancing execution system 204 may include an imbalance storage module 250. In various embodiments, the imbalance storage module 250 may be separate from the balancing execution system 204 and the imbalance estimation system 202. For example, in various embodiments, the imbalance storage module 250 may receive and send data to both the balancing execution system 204 and the imbalance estimation system 202.

With continued reference to FIG. 2, in an example embodiment, the measurement module 210 may comprise, for example, a current measurement circuit and a voltage measurement circuit. The current measurement module may comprise a current sensor, such as a hall effect sensor, a current shunt, or the like. The current sensor may be located convenient to measuring the current into or out of a cell (or a stack) in an ESS. It is noted that because the cells in the stack are in series, a measurement of the current into or out of the stack also represents the current into or out of each cell. The current measurement module is configured to sample current at a time step k, which may be, for example 1 second apart, though any sampling period can be used. In an example embodiment, the current measurement module can be any suitable current measurement device that is configured to measure a current (into or out of a single cell or the stack) and to generate a measured, actual current I_{M}, representing the cell or stack current measurements. The current measurement module may provide the current measurement I_{M} to SOC distribution estimation module 220.

In an example embodiment, the measurement module 210 may comprise, for example, a voltage measurement circuit. In an example embodiment, the voltage measurement module may comprise a voltage sensor, such as a capacitive voltage sensor, a resistive type voltage sensor, or the like. The voltage sensor may be located convenient to measuring the voltage across a cell in an ESS. In an example embodiment, the voltage measurement module can be any suitable voltage measurement device that is configured to measure a voltage and to generate a measured voltage, V, representing the voltage across a cell or across one or more portions of a module. The voltage measurements may be sampled at a time step k. In an example embodiment, k is 1 second apart, though any suitable time step can be used. In an example embodiment, the voltage measurement circuit may provide the voltage measurement Vm to the SOC distribution estimation module 220 and/or to the imbalance update module 260.

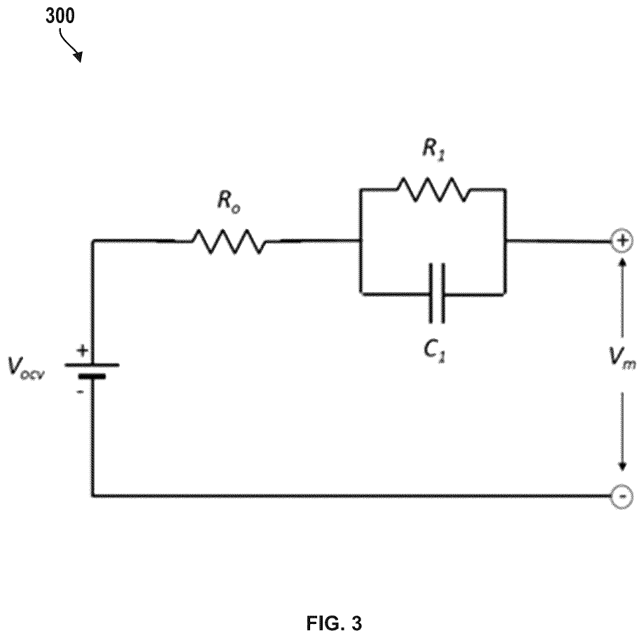

In an example embodiment, the SOC distribution estimation module 220 may be configured to generate an SOC estimate with uncertainty. In an example embodiment, the SOC distribution estimation module 220 may be configured to generate the SOC estimate with uncertainty based on a probabilistic battery model 230, using the measured current I_{M} and measured voltage V. In an example embodiment, the probabilistic battery model 230 may be an equivalent circuit model. In various embodiments, the equivalent circuit model may be a mathematical model of the battery's voltage response. The term probabilistic is used to reference the fact that the model accounts for uncertainty in one or more of the following areas: uncertainty in the measured current I_{M} and in the measured voltage V, uncertainty in the model parameters, or uncertainty in the battery model itself. For example, the SOC distribution estimation module 220 may use the probabilistic battery model 230 with an open circuit voltage model, a resistor element and one resistor-capacitor pair element, as show in FIG. 3. In various embodiments, the input into the cell model may be the measured current, I_{M}, which is used to predict the measured voltage Vₘ. In various embodiments, the input and prediction can be a single value or a probability distribution. In various embodiments, the circuit model 300 may comprise a resistance, Rₒ, in series with a resistance, R₁, across a first cell, C₁. The model parameters values Rₒ, R₁ and C₁ can be a single value or a probability distribution. Moreover, any suitable cell model may be used to predict the terminal voltage. In an example embodiment, the probabilistic battery model 230 may be used to estimate SOC and SOC estimation uncertainty, during operation, using the measured current Iₘ and the measured voltage V. The word operation means that the battery is not at rest and there is an applied current. The word operation can also mean the battery is in one of the following modes: charging, discharging, or floating.

With continued reference to FIG. 2, in an example embodiment, a SOC distribution estimation module 220 is configured to receive cell measurement inputs. The cell measurement inputs may include a voltage measurement for each cell in the stack, V_{m,1,k} . . . V_{m,N,k}, and a current measurement for the stack, I_{m,k}. The subscript n represents the specific cell n and the subscript k represents the time step. For example, V_{m,2,10} represents the measured voltage of cell 2 at the 10^{th} time step.

In various embodiments, the SOC distribution estimation module 220 is configured determine an SOC estimate with SOC estimation uncertainty. The SOC distribution estimation module 220 is configured to output an estimator output. The estimator output, in one example embodiment, is a SOC estimate with SOC estimation uncertainty. The SOC estimate with SOC estimation uncertainty may include the upper confidence intervals (or limit) for SOC of each cell from 1 . . . N, SOC_{u,1,k} . . . SOC_{u,N,k}, a lower confidence interval (or limit) for SOC of each cell, SOC_{l,1,k} . . . SOC_{l,N,k} and a mean SOC value for each cell, SOC_{m,1,k} . . . SOC_{m, N,k}. The upper confidence interval, the lower confidence interval and the mean SOC value may be determined based on the SOC estimate with SOC estimation uncertainty. The upper confidence interval, the lower confidence interval and the mean SOC value may be determined for each cell, n, and at each time step, k. In an example embodiment, the SOC estimate with SOC estimation uncertainty may be a probability distribution of SOC.

Thus, in various embodiments, the SOC distribution estimation module 220 is configured to measure or receive the cell measurement inputs. In various embodiments, SOC distribution estimation module 220 is configured to determine a SOC estimate with SOC estimation uncertainty. The SOC distribution estimation module 220 may determine (or estimate) the upper confidence interval SOC_{u,n,k}, lower confidence interval SOC_{l,n,k} and/or mean SOC value SOC_{m,n,k}, based on the SOC estimate with SOC estimation uncertainty. In an example embodiment, the SOC distribution estimation module 220 may provide the upper and lower confidence intervals and the mean SOC values to the imbalance estimation module 240. In various embodiments, the SOC distribution module 220 may estimate the upper confidence interval SOC_{u,n,k}, lower confidence interval SOC_{l,n,k} and/or mean SOC value SOC_{m,n,k}, based on a probabilistic battery model.

With continued reference to FIG. 2, in an example embodiment, the SOC distribution estimation module 220 is configured to generate SOC estimates and SOC estimation uncertainties using a probabilistic single RC pair equivalent circuit model. For example, the SOC distribution estimation module 220 may predict the terminal voltage, V_{m,n,k}, using the equation:

V_{m,n,k}=f_{ocv}(SOC_{n,k})−f_{dyn}(θₚ,I_{m,k})+ε_{model}
where f_{ocv}(SOC_{n,k}) is the open-circuit voltage (OCV) curve as a function of SOC, f_{dyn}(θₚ, Iₘ) is the battery voltage response to a current input and ε_{model} is the model error. The term f_{ocv}(SOC) can be provided by the manufacturer or can be determined empirically through testing of the energy storage device itself or similar energy storage devices. The nominal OCV curve may be a function or may be a look-up table-based function, or any suitable approach for determining the OCV value from an SOC estimate.

The term f_{dyn}(θₚ, Iₘ) represents the different voltage drops that are present in the battery when a current is applied. In an example embodiment, where the battery is represented as an equivalent circuit model with a single resistor R₀ and a single RC pair R₁ and C₁, the term f_{dyn}(θₚ, Iₘ) can be described by the following equation:

f_{dyn}(θₚ,Iₘ)=Vₜₕ+IₘR₀

Where Vₜₕ represents the voltage drop across the RC pair. In an example embodiment, the f_{dyn}(θₚ, Iₘ) term represent the voltage drops due to the current input into any suitable equivalent circuit model.

The equation above can be written in terms of SOC by isolating for SOC and taking the inverse function of the f_{ocv}(SOC), which is represented as f_{soc}(OCV). The SOC distribution estimation module 220 may calculate the SOC estimate using the equation:

SOC=f_{soc}(V_{m,n,k}+f_{dyn}(θₚ,Iₘ)+ε_{model})

In various embodiments, the SOC distribution estimation module 220 is configured to determine the SOC estimation uncertainty, by considering measurement noise in the terminal voltage V_{m,n,k}. In various embodiments, the measurement noise may be modeled using a normal distribution V_{m,n,k}˜N(μᵥ, σᵥ²), where the value of μ_{θ} and σ_{θ}² is dependent on the voltage sensor and can be determined experimentally. In various embodiments, the uncertainty in voltage measurement may be propagated to uncertainty in the SOC estimate using a propagation method described below.

In various embodiments, the SOC distribution estimation module 220 is configured to determine the SOC estimation uncertainty, by considering the error in the equivalent circuit model parameters, θₚ. The error in the model parameters, θₚ, may be modeled using a normal distribution θ˜N(μ_{θ}, σ_{θ}²), where value of μ_{θ} and σ_{θ}² can be determined by running carefully designed experiments as detailed in the reference in M. Mathew, M. Mastali, J. Catton, E. Samadani, S. Janhunen, and M. Fowler, “Development of an electro-thermal model for electric vehicles using a design of experiments approach” Batteries 4(2), 2018. The uncertainty in model parameters may be propagated to uncertainty in the SOC estimate using a propagation method described below.

In various embodiments, the SOC distribution estimation module 220 may be configured to determine the SOC estimation uncertainty, by considering error in the battery voltage model, ε_{model}. The error in battery voltage model may also be referred to as “lack of fit”. The error in battery voltage model may be treated as a random variable with a normal distribution ε_{model}˜N(μ_{model}, σ_{model}²), where μ_{model} is the model error and σ_{model} is the variance of the model error. In various embodiments, the error in battery voltage model may be estimated experimentally. In various embodiments, the uncertainty in model error may be propagated to uncertainty in the SOC estimate using a propagation method described below.

In an example embodiment, the error propagation technique may use various sampling methods. For example, the Monte Carlo sampling approach may be used to generate random samples for V_{m,n,k}, θ and ε_{model}, and propagate these errors to uncertainty in SOC using the SOC equation. In another example embodiment, rather than generating samples from the entire probability distribution of V_{m,n,k}, θ and ε_{model}, specific samples can be selected from the distribution representing 95% or 99% confidence limits. Using these samples at the upper and lower confidence intervals of the measurements and/or model parameters, the upper and lower confidence intervals of SOC may be generated. The probability distribution for SOC may include the upper and lower confidence intervals on SOC for each cell n in the stack at every time step k.

In another example embodiment, the probability distribution representing the uncertainty in the SOC estimate may be determined based on recursive Bayesian estimation techniques. In various embodiments, Bayesian filters may be used to estimate battery SOC. This algorithm refers to any probabilistic approach that recursively updates a given probability distribution based on measurement samples and a mathematical process model. The recursive Bayesian estimation may be based on the Bayesian approach, where the prior belief of a state may be continuously updated based on new measurements. An example of this is an extended Kalman filter, where the process and measurement noise may be assumed to be normally distributed. The recursive Bayesian estimation term may also refer to other probabilistic approaches such as a particle filter, where the noise distributions may be non-Gaussian.

The recursive Bayesian estimation techniques may estimate a mean value SOC_{m,n,k}, and the standard error for SOC, SE_{soc,n,k}. The upper limit confidence SOC, SOC_{U,n,k}, and lower limit confidence SOC, SOC_{L,n,k}, may be determined using the standard error, SE_{soc,n,k} using the equation:

SOC_{U,n,k}=SOC_{m,n,k}+αₖ*SE_{soc,n,k}

SOC_{L,n,k}=SOC_{m,n,k}−αₖ*SE_{soc,n,k}

where αₖ is the critical value for the desired confidence limits, and wherein αₖ can change over time. The SE_{soc,n,k} is the corresponding standard error for SOC_{m,n,k}. In an example embodiment, the upper and lower SOC limits can be generated at each time step k.

In various embodiments, any probability estimation technique may be used to determine the SOC estimate with SOC estimation uncertainty using a battery model with uncertainty. In various embodiments, the SOC distribution estimation module 220 may be configured to filter to address noise in the measurements.

With continued reference to FIG. 2, in an example embodiment, the imbalance estimation module 240 is configured to receive the SOC estimate with SOC estimation uncertainty for each cells 1 through N in the stack. The SOC estimate with SOC estimation uncertainty may include the upper confidence intervals for the SOC, SOC_{u,1,k} . . . SOC_{u,N,k}, the lower confidence interval for SOC, SOC_{l,1,k} . . . SOC_{l,N,k} and the mean SOC value, SOC_{m,1,k} . . . SOC_{m,N,k}.

In various embodiments, the imbalance estimation module 240 is configured to output the imbalance estimates for each cell, Δ_{C,n}, and the imbalance estimation uncertainty, W_{α}. The imbalance estimate may also be referred to as the imbalance value. In various embodiments, the imbalance estimate with imbalance estimation uncertainty may also be referred to as an imbalance estimate or uncertainty calculation. In various embodiments, the imbalance estimate with imbalance estimation uncertainty may comprise a probability distribution. For example, the imbalance value, Δ_{C,n} of greater than zero represents the amount of charge that needs to be removed from a cell by the balancing circuit and the imbalance estimation uncertainty, W_{α}, is used to determine whether or not to update the imbalance storage module 250 with a new imbalance update.

In various embodiments, the imbalance estimation module 240 is configured to receive the SOC estimates and SOC estimation uncertainty, determine how much imbalance is present in each cell based on the SOC values, and output an imbalance estimate with imbalance estimation uncertainty to the imbalance storage module 250.

In an example embodiment, the imbalance estimation module 240 is configured to estimate the imbalance. In various embodiments, estimating the imbalance may comprise (1) selecting the target cell, (2) determining the subset of cells with imbalance values that are statistically significant, and (3) estimating the imbalance estimate and imbalance estimation uncertainty for this subset of cells.

In various embodiments, some or all of the cells in the stack are discharged to match the SOC of the target cell. For example, if cell #1 has an SOC of 92%, cell #2 has an SOC of 94% and cell #3 has an SOC of 87%, and if the target cell is #3, then all the other cells need to be discharged to 87% SOC. In an example embodiment, the imbalance estimation module 240 may select the target cell based on calculating the mean of a plurality of SOC estimates, SOC_{m,1,k} . . . SOC_{m, N,k} and selecting the cell with a SOC that is closest to the mean of the target cell. In various embodiments, the target cell, c, may be the cell with a SOC that is closest to the median SOC value. In various embodiments, the target cell may be the cell with the SOC that is the minimum SOC value. The SOC of the target cell is represented as SOC_{m,c,k}.

In an example embodiment, the imbalance estimation module 240 may determine the subset of cells that have an imbalance that is statistically significant. For example, the imbalance estimation module 240 may calculate an imbalance of least 1 Ah charge with a 95% confidence limit or a 99% confidence limit. In accordance with an example embodiment, the imbalance is at least 1 Ah 95% of the time or 99% of the time. However, any suitable Ah and % numbers may be used.

In an example embodiment, the imbalance estimation module 240 is configured to estimate the critical distance value, d_{n,k}. The critical distance d_{n,k} is one approach to determining whether the imbalance estimates are statistically significant. In various embodiments, the critical distance value, d_{n,k}, may be calculated for each cell by taking the difference between the lower SOC limit of cell n, SOC_{L,n,k}, and the upper SOC limit of the target cell, SOC_{U,c,k} as shown in the equation:

d_{n,k}=SOC_{L,n,k}−SOC_{U,c,k}.

In accordance with an example embodiment, the imbalance estimation module 240 is configured such that where the critical distance value, d_{n,k}, is greater than zero an imbalance is considered statistically significant. In various embodiments, only a subset of cells with a positive critical distance value are considered for imbalance estimation. In an example embodiment, any approach for determining the subset of cells that have statistically significant imbalance values using the SOC estimation uncertainty can be used.

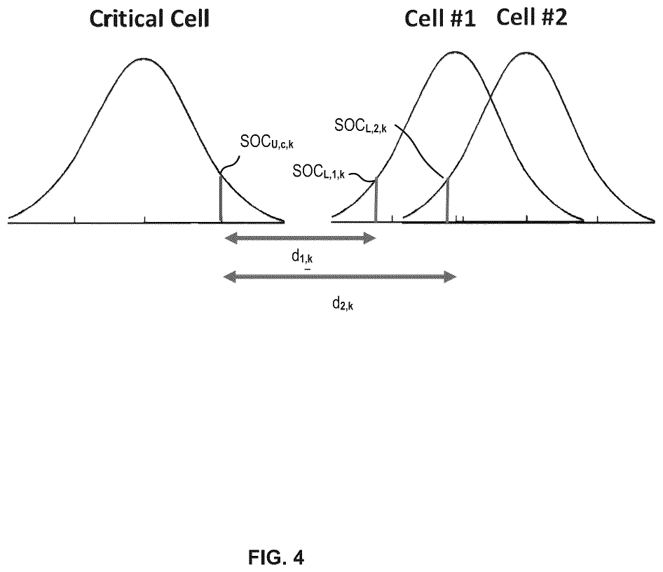

With reference to FIG. 4, the critical distance value may be calculated for a first cell and a second cell. For example, the critical distance value of cell #1, d_{1,k}, is equal to the difference between the lower SOC limit of cell #1, SOC_{L,1,k}, and the upper SOC limit of the target cell, SOC_{U,c,k}. For example, the critical distance value of cell #2, d_{2,k}, is equal to the difference between the lower SOC limit of cell #2, SOC_{L,2,k}, and the upper SOC limit of the target cell, SOC_{U,c,k}. For example, in various embodiments, since the critical distance in this example is greater than zero for both cell #1 and cell #2, this means that both cells have statistically significant imbalance values.

In various embodiments, the imbalance estimation module 240 is configured to estimate imbalance and imbalance estimation uncertainty for the subset of cells that was found to have statistically significant imbalance. In an example embodiment, the imbalance estimation module 240 is configured to estimate the imbalance estimate, Δ_{C,n}, for one or more of the cells and an imbalance estimation uncertainty, W_{α}. In various embodiments, the imbalance estimation module 240 may receive a SOC estimate, a SOC upper confidence interval, and a SOC lower confidence interval for one or more of the cells. In an example embodiment, the imbalance value can represents N imbalance values and the imbalance estimation uncertainty can represent N imbalance estimation uncertainties. In various embodiments, the imbalance estimation module 240 calculates the imbalance estimation uncertainty for a subset of cells. For example, if the critical distance value, d_{n,k} for a cell, n, is greater than zero, the imbalance estimation module 240 may be configured to calculate the imbalance estimation uncertainty, W_{α,k}, according to the equation:

$${W}_{a , k} = {\sum }_{i = 1}^{I} \frac{( {SOC}_{U , i , k} - {SOC}_{L , i , k} )}{I}$$

where i is the index of all cells with a d_{n,k} value greater than zero, and I is the total number of cells with a d_{n,k} value above zero. In an example embodiment, any suitable approach for determining the imbalance estimation uncertainty can be used.

The imbalance estimation module 240 may calculate the imbalance estimate, Δ_{c,n,k}, in units of Ah by taking the difference between the lower SOC value of cell n, SOC_{L,n,k} and the upper SOC value of the target cell, SOC_{U,c,k}, and multiplying the difference by the stack capacity, C_{stack}, as shown by the equation:

Δ_{c,n,k}=(SOC_{L,n,k}−SOC_{U,c,k})*C_{stack}

The C_{stack} may be assigned statically based upon the cell nameplate ratings, may be updated dynamically based upon measured charge flow over a full discharge cycle, or may be estimated using other suitable capacity estimation approaches.

In various embodiments, the imbalance storage module 250 is configured to store the imbalance estimate, Δ_{c,n,k}, if either there are no entries in the imbalance storage module, or the value W_{α,k} calculated at the k^{th} time step is less than the value of W_{α} currently stored in the imbalance storage module 250.

With continued reference to FIG. 2, in an example embodiment, the imbalance storage module 250 is configured to receive and store the imbalance values, Δ_{c,n}, and imbalance estimation uncertainty, W_{α}. For example, the imbalance estimation module 240 may store the imbalance value, Δ_{c,n}, for each cell in the stack, and the imbalance estimation uncertainty, W_{α} based on the average of all the cells in the stack with statistically significant imbalance estimates. In various embodiments, the imbalance estimation module 240 may update the imbalance storage module 250 with the imbalance value, Δ_{c,n}, and the imbalance estimation uncertainty W_{α} when a new estimate of imbalance is generated. In various embodiments, the imbalance estimation module 240 may update the imbalance storage module 250 with the imbalance value, Δ_{c,n}, when the hardware balancing module 280 has been enabled.

In various embodiments, the imbalance storage module 250 is configured to provide imbalance values to the imbalance update module 260 and the balancing prediction module 270. In various embodiments, the imbalance storage module 250 may provide the cell level imbalance values to the user for diagnostic purposes. The cell level imbalance values (Δ₁ . . . Δ_{N}) may be provided to the user as a capacity value (e.g Ah) or an energy value (e.g. kWh). The cell level imbalance value may be converted to the total time required to bring the stack to balance (t_{B,1} . . . t_{B,N}) for cell n and this value can also be provided to the user.

With continued reference to FIG. 2, in an example embodiment, the balancing prediction module 270 is configured to receive one or more temperature measurements. The one or more temperature measurements may include a balancing circuit temperature value. The balancing prediction module 270 may receive multiple temperature readings, T_{b,1,k} . . . T_{b,L,k}, from the hardware balancing module 280. In various embodiments, the balancing prediction module may be configured to receive an imbalance value. For example, the imbalance value may include multiple imbalance estimates, Δ_{c,n,k} . . . Δ_{c,N,k}, from the imbalance storage module 250. In an example embodiment, the balancing circuit in the hardware balancing module 280, can be individual hardware units that are separate from each other, and have their own unique temperature sensors.

In various embodiments, the balancing prediction module 270 is configured to send a balancing signal, S_{n,k} for one or more of the cells. In various embodiments, the balancing prediction module 270 may send the balancing signal, S_{n,k}, to the hardware balancing module 280 and/or the imbalance update module 260. The balancing signal, S_{n,k}, may be used to discharge one or more of the cells. The balancing signal, S_{n,k}, may be a Boolean signal that represents whether or not to balance. In various embodiments, the balancing signal, S_{n,k}, may be set to 1 if the balancing circuit temperature reading T_{b,l,k} associated with cell n, is lower than a configurable threshold temperature T_{c}, and the imbalance estimate Δ_{c,n,k}, is greater than zero for cell n. In an example embodiment, if multiple temperature readings are available that corresponds to a specific cell n, then the balancing signal S_{n,k} can be determined by taking the maximum of the temperature readings and checking this value against a configurable threshold temperature T_{c}. If the value of the imbalance estimate Δ_{c,n,k} is greater than zero, this means there is still additional imbalance in the stack that needs to be removed.

In various embodiments, any type of control loop may be used for maintaining the balancing circuit temperature T_{b,l,k} below a configurable threshold. In various embodiments, any type of control loop may be used for decreasing the remaining imbalance in the stack Δ_{c,n,k} to zero.

With continued reference to FIG. 2, in an example embodiment, the hardware balancing module 280 may comprise a hardware balancing circuit. In various embodiments, the hardware balancing module 280 may be configured to receive the balancing signal, S_{n,k}. The balancing signal. S_{n,k} may specify whether one or more cells are balanced or not. In an example embodiment, a Boolean value of 1 represents the balancing switch should be closed while a Boolean value of 0 means the switch should be open. In various embodiments, an closed balancing switch may allow a small amount of current to bleed from the cell, while an open switch means no charge is removed from the cell. In various embodiments, the balancing signal S_{n,k} may represent any way of communicating whether to balance or not. In various embodiments, the hardware balancing module 280 can contain a temperature sensor that is configured to measure a temperature and to generate a measured temperature, T_{b}, representing the temperature at the balancing resistor. There can be l=1 . . . L number of temperature sensors on the balancing circuits found in the hardware balancing module 280. Although the number of sensors can equal the number of cells, this is not often the case due to space and cost restrictions. In various embodiments, the temperature measurements may be sampled at a time step k. In various embodiments, the balancing circuit temperature T_{b,l,k} may be used as a feedback to the balancing prediction module 270 to ensure the balancing circuit does not overheat.

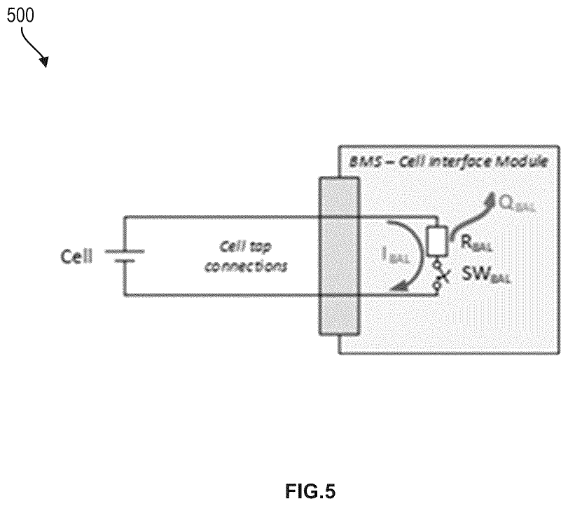

In an example embodiment, the hardware balancing module 280 may comprise a balancing circuit 500, as shown in FIG. 5. In an example embodiment, the balancing circuit 500 may be used to discharge a small amount of current from an imbalanced cell. In an example embodiment, the balancing circuit 500 may include a balancing circuit R_{BAL} and a software balancing switch SW_{BAL}. When the balancing signal S_{n,k} for cell n is set to 1, the balancing switch is closed and a small balancing current is discharged from the battery. In various embodiments, the balancing circuit may be used to discharge a small amount of current from the individual cell.

In an example embodiment, any type of hardware circuit can be used that bleeds a small amount of charge from individual cells.

With continued reference to FIG. 2, in an example embodiment, the imbalance update module 260 is configured to receive imbalance measurements for each cell in the stack. In various embodiments, the imbalance update module 260 may receive the cell measurement voltage, V_{m,n,k}, the balancing signal, S_{n,k}, and the imbalance estimate Δ_{c,n,k}. In various embodiments, the imbalance update module 260 may receive the cell measurement voltage, V_{m,n,k}, from the measurement module 210. In various embodiments, the imbalance update module 260 may receive the balancing signal, S_{n,k}, from the balancing prediction module 270. In various embodiments, the imbalance update module 260 may receive the imbalance estimate Δ_{c,n,k} from the imbalance storage module 250. In various embodiments, the imbalance update module 260 may receive the measurement voltage, V_{m,n,k}, the balancing signal, S_{n,k}, and the imbalance estimate Δ_{c,n,k} at each time step, k.

In various embodiments, the imbalance update module 260 is configured to output an updated imbalance estimate at the time step k+1, Δ_{c,n,k+1}, to the imbalance storage module 250. In various embodiments, the imbalance storage module 250 is configured to store the updated imbalance estimate, Δ_{c,n,k+1,}

In various embodiments, the imbalance update module 260 is configured to update the imbalance estimate, Δ_{c,n,k}, using a simulated balancing circuit. The imbalance update module 260 may update the imbalance value based on a simulated balancing circuit model. In various embodiments, the simulated balancing circuit is similar to the balancing hardware. In various embodiments, where the balancing circuit is composed of a single balancing resistor R_{BAL}, the new imbalance estimate, Δ_{c,n,k+1}, for the next time step, k+1, can be estimated as:

$${Δ}_{c , n , k + 1} = {Δ}_{c , n , k} - ( \frac{{V}_{m , n , k}}{{R}_{B A L}} ) ( \frac{Δ t}{3600} )$$

Where R_{BAL} is the balancing resistor in Ohms, Δt is the measurement time step in seconds, and Δ_{c,n,k} is the imbalance charge in Ah.

In various embodiments, the simulated balancing circuit may be any mathematical model or equation that represents a balancing circuit. In an example embodiment, the imbalance update module 260 only updates the stored imbalance estimate when the balancing signal S_{n,k}, indicates that the system is not balanced. The imbalance update module 260 will gradually decrease the imbalance estimates stored in the imbalance storage module 250 based on how much balancing current is removed from the cell. Note that this is different from the imbalance estimation module that generates an estimate of the imbalance from measurement data.

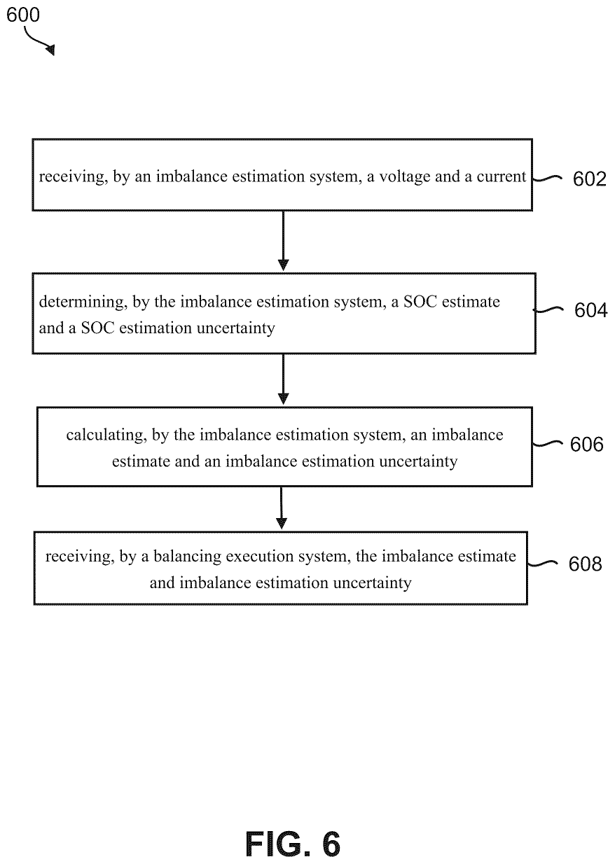

With reference to FIG. 6, in various embodiments a method 600 of executing cell balancing is disclosed. The example method includes receiving, by an imbalance estimation system, a voltage and a current associated with one or more cells of an energy storage device (602). For example, a current measurement module may measure a current related to the energy storage system to ascertain a measured current. (See, for example, current I_{M}, I_{M,1 . . . J}.) The current may be measured using a current measurement circuit. In accordance with various example embodiments, the method may further comprise measuring one or more voltage(s) related to the energy storage system to ascertain measured voltage(s).

In an example embodiment, the method further comprises determining, by the imbalance estimation system. In various embodiments, the imbalance estimation system may determine an SOC estimate and a SOC estimation uncertainty of the energy storage device based on the voltage and the current of the energy storage device (604). The method may comprise calculating, by the imbalance estimation system, an imbalance estimate of one or more of the cells of the energy storage device and imbalance estimation uncertainty (606).

Moreover, in an example embodiment, the method 600 may further comprises receiving, by a balancing execution system, imbalance estimate and imbalance estimation uncertainty associated with the energy storage device (608).

In an example embodiment, the cell balancing system 200 may be used in the context of stationary energy storage applications, for generating balanced stacks for the ESS. In another example embodiment, the cell balancing system 200 may be used in the context of second-life applications for batteries. For example, a battery pack in a vehicle may no longer be able to meet the vehicle energy requirements, but may provide sufficient energy capacity and power for an alternative function such as stationary energy storage applications. In another example embodiment, the cell balancing system 200 may be used in the context of an electric vehicle (e.g. passenger vehicle, delivery vehicle, autonomous vehicle, and/or the like). In another example embodiment, the cell balancing system 200 may be used in the context of specialty vehicles such as an electric forklift or golf carts. In another example embodiment, the cell balancing system 200 may be used in the context of trains or long haul trucking (e.g. where a fuel cell or other energy source charges an energy storage device on the train or truck). In another example embodiment, the cell balancing system 200 may be used in the context of airplanes. In another example embodiment, the cell balancing system 200 may be used in the context of a test fixture (such as in a lab) to balance a stack for one or more energy storage devices within a more controlled environment.

Accordance with various example embodiments, the systems, methods and devices of the present disclosure are applicable at the cell level, at the device level, at the ESS level, and in the context of a stack of cells, a stack of modules, and/or a bank.

Example embodiments of the systems, methods, and devices described herein may be implemented in hardware, software, firmware, or some combination of hardware, software, and firmware. For example, the block diagrams of FIG. 2 may be implemented in hardware, software, firmware, or some combination of hardware, software, and firmware. For example, a module or combinations of modules in FIG. 2 may be implemented in hardware, software, firmware, or some combination of hardware, software, and firmware. For example, the measurement module 210 of FIG. 2 may be implemented in hardware, software, firmware, or some combination of hardware, software, and firmware. The SOC distribution estimation module 220 of FIG. 2 may be implemented in hardware, software, firmware, or some combination of hardware, software, and firmware. In an example embodiment, the imbalance estimation module 240 may be implemented on a processor (hardware) running code (software) causing the processor to calculate an integral of an input signal over time. Similarly, one or more modules in component in FIG. 2 may include hardware, software, or some combination thereof. Furthermore, the method described with respect to FIG. 5 may be implemented in hardware, software, firmware, or some combination of hardware, software, and firmware.

In the present disclosure, the following terminology will be used: The singular forms “a,” “an,” and “the” include plural referents unless the context clearly dictates otherwise. Thus, for example, reference to an item includes reference to one or more items. The term “ones” refers to one, two, or more, and generally applies to the selection of some or all of a quantity. The term “plurality” refers to two or more of an item. The term “about” means quantities, dimensions, sizes, formulations, parameters, shapes, and other characteristics need not be exact, but may be approximated and/or larger or smaller, as desired, reflecting acceptable tolerances, conversion factors, rounding off, measurement error and the like and other factors known to those of skill in the art. The term “substantially” means that the recited characteristic, parameter, or value need not be achieved exactly, but that deviations or variations, including, for example, tolerances, measurement error, measurement accuracy limitations and other factors known to those of skill in the art, may occur in amounts that do not preclude the effect the characteristic was intended to provide. Numerical data may be expressed or presented herein in a range format. It is to be understood that such a range format is used merely for convenience and brevity and thus should be interpreted flexibly to include not only the numerical values explicitly recited as the limits of the range, but also interpreted to include all of the individual numerical values or sub-ranges encompassed within that range as if each numerical value and sub-range is explicitly recited. As an illustration, a numerical range of “about 1 to 5” should be interpreted to include not only the explicitly recited values of about 1 to about 5, but also include individual values and sub-ranges within the indicated range. Thus, included in the numerical range are individual values such as 2, 3 and 4 and sub-ranges such as 1-3, 2-4 and 3-5, etc. The same principle applies to ranges reciting only one numerical value (e.g., “greater than about 1”) and should apply regardless of the breadth of the range or the characteristics being described. A plurality of items may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. Furthermore, where the terms “and” and “or” are used in conjunction with a list of items, they are to be interpreted broadly, in that any one or more of the listed items may be used alone or in combination with other listed items. The term “alternatively” refers to selection of one of two or more alternatives, and is not intended to limit the selection to only those listed alternatives or to only one of the listed alternatives at a time, unless the context clearly indicates otherwise.

It should be appreciated that the particular implementations shown and described herein are illustrative of the example embodiments and their best mode and are not intended to otherwise limit the scope of the present disclosure in any way. Furthermore, the connecting lines shown in the various figures contained herein are intended to represent exemplary functional relationships and/or physical couplings between the various elements. It should be noted that many alternative or additional functional relationships or physical connections may be present in a practical device.

As one skilled in the art will appreciate, the mechanism of the present disclosure may be suitably configured in any of several ways. It should be understood that the mechanism described herein with reference to the figures is but one exemplary embodiment of the disclosure and is not intended to limit the scope of the disclosure as described above.

It should be understood, however, that the detailed description and specific examples, while indicating exemplary embodiments of the present disclosure, are given for purposes of illustration only and not of limitation. Many changes and modifications within the scope of the instant disclosure may be made without departing from the spirit thereof, and the disclosure includes all such modifications. The corresponding structures, materials, acts, and equivalents of all elements in the claims below are intended to include any structure, material, or acts for performing the functions in combination with other claimed elements as specifically claimed. The scope of the disclosure should be determined by the appended claims and their legal equivalents, rather than by the examples given above. For example, the operations recited in any method claims may be executed in any order and are not limited to the order presented in the claims. Moreover, no element is essential to the practice of the disclosure unless specifically described herein as “critical” or “essential.”

What is claimed:

1. A cell balancing device in an energy storage system, comprising:
one or more cells of an energy storage device;
an imbalance estimation system configured to determine an imbalance estimate of the one or more cells based on:
a voltage input, V, representing a measured voltage associated with the energy storage device, and
a probabilistic battery model associated with the energy storage device; and
a balancing execution system comprising a balancing circuit, the balancing execution system configured to partially discharge the one or more of the cells via the balancing circuit based on the imbalance estimate of one or more of the cells.

2. The cell balancing device of claim 1, wherein the balancing execution system comprises a balancing resistor, a software balancing switch and a cell tap connection, and the balancing execution system is configured to discharge a balancing current from the one or more cells based on:
the voltage input, V, and
a balancing circuit model representing the balancing circuit.

3. The cell balancing device of claim 1, wherein the imbalance estimate the energy storage device is further based on a current input of the energy storage device.

4. The cell balancing device of claim 1, wherein the imbalance estimation system further comprises a SOC distribution estimation module, the SOC distribution estimation module is configured to:
receive the voltage input, V, and the probabilistic battery model; and
estimate a SOC estimate and a SOC estimation uncertainty for the one or more cells.

5. The cell balancing device of claim 4, wherein the imbalance estimation system further comprises an imbalance estimation module and an imbalance storage module;
the imbalance estimation module configured to receive the SOC estimate and the SOC estimation uncertainty for the one or more cells and estimate the imbalance estimate and an imbalance estimation uncertainty for the one or more of cells; and
wherein the imbalance estimate and the imbalance estimation uncertainty is stored in the imbalance storage module.

6. The cell balancing device of claim 5, wherein the imbalance estimation module is configured to update the imbalance estimate of the one or more of cells when the imbalance estimate is statistically significant based on the SOC estimation uncertainty and the imbalance estimation uncertainty.

7. The cell balancing device of claim 1, wherein the balancing execution system further comprises a balancing prediction module configured to:
receive the imbalance estimate for the one or more cells and a balancing circuit temperature value; and
send a balancing signal for the one or more cells to a hardware balancing module for partially discharging the one or more cells.

8. The cell balancing device of claim 7, wherein the balancing execution system further comprises an imbalance update module configured to:
receive the balancing signal for the one or more cells; and
update the imbalance estimate for the one or more cells based on a balancing circuit model.

9. A battery balancing system for executing cell balancing, comprising:
a battery stack comprising one or more cells;
an imbalance estimation system configured to determine an imbalance estimate of the battery stack based on:
a voltage associated with the one or more cells of the battery stack;
a current associated with the battery stack;
a probabilistic battery model associated with the one or more cells of the battery stack; and
a balancing execution system configured to receive the imbalance estimate for the one or more cells, and to discharge a balancing current from the one or more cells using a balancing circuit.

10. The system of claim 9, wherein the imbalance estimation system further comprises a SOC distribution estimation module configured to:
receive the voltage associated with the one or more cells of the battery stack and the current associated the battery stack; and
estimate a SOC estimate, a SOC upper confidence interval and a SOC lower confidence interval for the one or more cells.

11. The system of claim 10, wherein the imbalance estimation system further comprises an imbalance estimation module configured to:
receive the SOC estimate, the SOC upper confidence interval and the SOC lower confidence interval for the one or more cells; and
estimate the imbalance estimate and an imbalance estimation uncertainty for the one or more cells based on the SOC estimate, the SOC upper confidence interval and the SOC lower confidence interval.

12. The system of claim 11, wherein the imbalance estimation module is configured to:
update the imbalance estimate of the one or more cells when the imbalance estimate is statistically significant based on the SOC estimate, the SOC upper confidence interval, the SOC lower confidence interval, and the imbalance estimation uncertainty.

13. The system of claim 9, wherein the balancing execution system further comprises a balancing prediction module configured to:
receive the imbalance estimate for the one or more cells; and
send a balancing signal for the one or more cells to the balancing circuit for discharging one or more of the cells, based on the imbalance estimate.

14. The system of claim 13, wherein the balancing execution system further comprises an imbalance update module configured to:
receive the balancing signal for the one or more cells; and
update the imbalance estimate for the one or more cells based on a balancing circuit model.

15. A method for executing cell balancing, comprising:
receiving, by an imbalance estimation system, a voltage and a current associated with one or more cells of an energy storage device;
determining, by the imbalance estimation system, an SOC estimate and a SOC estimation uncertainty of the energy storage device based on the voltage and the current associated with the one or more cells of the energy storage device;
calculating, by the imbalance estimation system, an imbalance estimate of the one or more cells of the energy storage device and an imbalance estimation uncertainty; and
receiving, by a balancing execution system, the imbalance estimate and the imbalance estimation uncertainty associated with the energy storage device.

16. The method for executing cell balancing of claim 15, further comprising:
storing, by the balancing execution system, the imbalance estimate for the one or more cells and the imbalance estimation uncertainty; and
discharging, by the balancing execution system, a balancing current from the one or more cells of the energy storage device based on the imbalance estimate and the imbalance estimation uncertainty;
wherein the balancing execution system comprises a balancing circuit and a balancing circuit model representing the balancing circuit.

17. The method for executing cell balancing of claim 16, wherein the imbalance estimation system further comprises a SOC distribution estimation module, comprising:
receiving, by the SOC distribution estimation module, the voltage for the one or more cells, the current associated with the one or more cells; and
estimating, by the SOC distribution estimation module, the SOC estimate, a SOC upper confidence interval and a SOC lower confidence interval for the one or more cells, based on a probabilistic battery model.

18. The method for executing cell balancing of claim 17, wherein the imbalance estimation system further comprises an imbalance estimation module, the method further comprising:
receiving, by the imbalance estimation module, the SOC estimate, the SOC upper confidence interval and the SOC lower confidence interval for the one or more cells; and
estimating, by the imbalance estimation module, the imbalance estimate for one or more of the cells and the imbalance estimation uncertainty.

19. The method for executing cell balancing of claim 18, wherein the balancing execution system further comprises a balancing prediction module, the method further comprising:
receiving, by the balancing prediction module, the imbalance estimate, and a temperature measurement; and
sending, by the balancing prediction module, a balancing signal for one or more of the cells to the balancing circuit for discharging one or more of the cells.

20. The method for executing cell balancing of claim 19, wherein the balancing execution system further comprises an imbalance update module and an imbalance storage module, the method further comprising:
receiving, by the imbalance update module, the balancing signal for the one or more cells; and
updating, by the imbalance update module, the imbalance estimate in the imbalance storage module based on the balancing circuit model.
